(19) United States
(12) Patent Application Publication
(10) Pub. No.: US 2008/0286959 A1
(43) Pub. Date: Nov. 20, 2008

(54) Downhill Wire Bonding for QFN L - Lead

(75) Inventor: Meng Thee Chia, Petaling Jaya (MY)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/747,987

(22) Filed: May 14, 2007

(51) Int. Cl. H01L 21/44

(52) U.S. Cl. 438/617; 257/E21.476

(57) ABSTRACT

Downhill wire bonding process for QFN is performed with a capillary using goldwire that connects die (the Integrated Circuit or the substrate) and the stitch platform also called lead fingers. The goldwire is molten into a ball by applying high current. The molten ball is compressed against the bond pads of the integrated circuit using high temperature and ultrasonic energy. To complete the connection, the capillary is lifted vertically from the bond pads of the die or integrated circuit to loop over to the lead finger so that the goldwire is compressed against the lead finger with a reduced angle of approach of the capillary. Downhill wire bonding of the lead frames is advantageously addressed by increasing the thickness of the stitch platform so as to reduce the angle of approach of the capillary during the downhill wire bonding process between various components of the semiconductor.

Another way of reducing the angle of approach of the capillary is also reduce the height by which the capillary is lifted vertically from the die or integrated circuit before it loops over to the lead fingers.

### FIELD OF THE INVENTION

The invention relates to the packaging of semiconductor devices and more particularly to a device and a method of downhill wire bonding between the bond pads of the integrated circuit and lead fingers while lessening thermal and mechanical stress of downhill wire bonding by reducing the angle of approach of the capillary in the downhill wire bonding.

### BACKGROUND OF THE INVENTION

Various techniques are used for packaging integrated circuits and for wire bonding between different locations of a semiconductor die, as well as between the semiconductor die and an external location such as a lead finger on a lead frame. The lead fingers are generally formed of copper or a copper alloy such as A42 and the bond pads on the die are generally aluminum. Wire bonding is performed by placing a capillary over a bond pad of the semiconductor die for making a ball bond with a ball of the wire extending out of the capillary and bonding the ball to the bond pad. The capillary is then moved to a lead finger of the lead frame to which a bond is to be made with the wire traveling with respect to the capillary bore and a stitch bond is then made to the lead finger using the capillary with the wire then being broken, leaving a small wire pigtail extending out of the capillary.

In many applications, such as wireless technologies or miniature electronic devices, it is desirable to reduce the thickness of the final packaging. And with the continued miniaturization of the packaging of semiconductor devices, in spite of the use of sophisticated bonding techniques such as the Ball Grid Array (BGA) or the Mini Ball Grid Array (MBGA), it is necessary to maintain and if possible to improve the reliability of wire bonding for such thin packages.

As previously mentioned, wire bonding techniques form the wire connection between the bond pads of the semiconductor die and the lead fingers of the lead frame by forming a ball bond on the bond pads of the semiconductor die and looping the wire up and over to the lead fingers where the stitch bonds are formed to complete the wire bonding.

Furthermore, by looping the wire up and down to complete the wire bonding, the capillary creates a stress on the wire which depends on the curvature and more particularly on the angle of approach. The stress on the wire is proportional to the angle of approach of the wire bonding. The higher the angle of approach is, the more important the stress become. This causes the heel of the stitch bond to crack or to break away from the surface of contact and therefore to be unreliable, which leads to diminished yield due to faulty bonding.

The QFN package is a particular IC packaging that gained attention in the early 2001 as the latest package being no-lead that offered size reduction and good electrical performance especially for high power with exposed die pad and short leads within the package. In some QFN packages, the miniature electronic devices may require three wires connected to one lead finger. With this type of exposed die pad, the resulting wire bonding angle is increased since the wire bonding between the die and the lead finger is a downhill bonding.

As for traditional packaging, broken heel stitch is a serious reliability issue which cannot always be detected by test. Despite actions taken to enhance the wire bonding process that, showed reduction in the number of broken heel stitches, reliable wire bonding needs still to be improved especially in the case of configuration where more than one wire is connected to a lead finger. For instance in a configuration where three bonding wires are connected to a single lead finger, a broken heel stitch will cause the three bonding wires to be disconnected from the lead finger.

### SUMMARY OF THE INVENTION

The summary of the invention provides a basic understanding of some aspects of the invention. It is not an extensive overview of the invention. It is intended to neither identify key or critical elements of the invention nor delineate the scope of the invention. Its purpose is to present some concepts of the invention in a simplified form as a prelude to a more detailed description that is presented in connection with accompanying drawings.

In accordance with the present invention, the above noted problem which is inherent to downhill wire bonding of the lead frames is advantageously addressed by reducing the angle of approach of the capillary during the downhill wire bonding process between various components of the semiconductor. The stitch platform is welded with a gold wire that loops from the semiconductor die to the lead finger or stitch platform. It is done using the thermosonic process meaning a welding process at high temperature with ultrasound.

The downhill wire bonding process for QFN is performed with a capillary using goldwire that connects the semiconductor die (substrate or the Integrated Circuit) to the lead fingers or stitch platform. The goldwire is molten into a ball by applying high current. The molten ball is compressed against the bond pads of the integrated circuit using temperature and ultrasonic energy. To complete the connection, the capillary is lifted vertically from the bond pads of the semiconductor die to loop over to the lead finger and the goldwire is compressed against the lead finger or the stitch platform with a reduced angle of approach of the capillary.

There are two factors that enable to reduce the angle of approach of the capillary: increase the thickness of the lead finger or the stitch platform and/or reduce the height by which the capillary is lifted vertically from the semiconductor die before it loops over to the lead finger or the stitch platform.

According to one embodiment, a method of downhill wire bonding between an integrated circuit and a plurality of lead fingers comprises the steps of:

(a) forming a stitch bond on a wire bonding location on a die pad of the integrated circuit;

(b) lifting vertically the wire by a height;

(c) moving the wire away from the wire bonding location on said die pad of the integrated circuit to one of said plurality of lead fingers;

(d) approaching one of said plurality of lead fingers with a reduced angle of approach;

(e) forming a stitch bond on one of said plurality of lead fingers; and

(f) bonding said one of said plurality of lead fingers to said die pad of the integrated circuit with a bonding wire which has a reduced angle with the surface of the lead finger.

According to another embodiment, a method of downhill wire bonding between an integrated circuit and a plurality of lead fingers comprises the steps of:

(a) etching each said plurality of lead fingers to increase lead finger thickness;

(b) providing lead frame with said plurality of lead fingers with increased thickness;

(c) providing integrated circuit with a plurality of bonding pads;

(d) applying adhesive to bond integrated circuit to a lead frame die; and

(e) approaching a capillary with a reduced angle of approach to bond said plurality of bonding pads of the integrated circuit to said plurality of lead fingers with a bonding wire threaded through the bore of a capillary.

The embodiments advantageously provide an improved QFN (L-lead semiconductor package which comprises an integrated circuit bonded to a lead frame die with an adhesive, said integrated circuit having a plurality of die pads; and a plurality of lead fingers electrically wire bonded with said plurality of die pads of said integrated circuit; wherein each said plurality of lead fingers presents an increased stitch platform thickness.

### BRIEF DESCRIPTION OF THE DRAWINGS

For a more complete understanding of the present invention and the advantages thereof, reference is now made to the following detailed description taken in conjunction with the accompanying drawings, in which:

FIG. 1 is a plan view of a QFN L-lead design according to the prior art.

FIG. 2 is a partial cross-sectional view A-A of the QFN L-lead design according to the prior art.

FIG. 3 shows the heel of a stitch bond in a perspective view.

FIG. 4 shows a small crack of the heel of a stitch bond in an elevation view.

FIG. 5 is a plan view of a QFN L-lead design with an increased stitch platform on the lead finger according to the present invention.

FIG. 6 is a partial cross-sectional view B-B of the QFN L-lead design with an increased stitch platform or lead finger according to the present invention.

FIGS. 7a and 7b show the comparison of partial cross-sectional view C-C between a design without an increased stitch platform or lead finger and a design with an increased stitch platform or lead finger and a reduction in the height of capillary lift.

FIG. 8 is another partial cross-sectional view C-C of another QFN L-lead design with an increased stitch platform or lead finger in more details.

FIG. 9 is a block diagram of an exemplary method for manufacturing a QFN L-lead with an increased stitch platform or lead finger.

### DETAILED DESCRIPTION OF THE INVENTION

The preferred embodiment of the present invention and its advantages are best understood by referring to the drawings, like numerals being used for like and corresponding parts of the various drawings.

The present invention is directed towards a device and process for reducing the mechanical and thermal stress of stitch bonding by reducing the angle of approach of the downhill wire bonding.

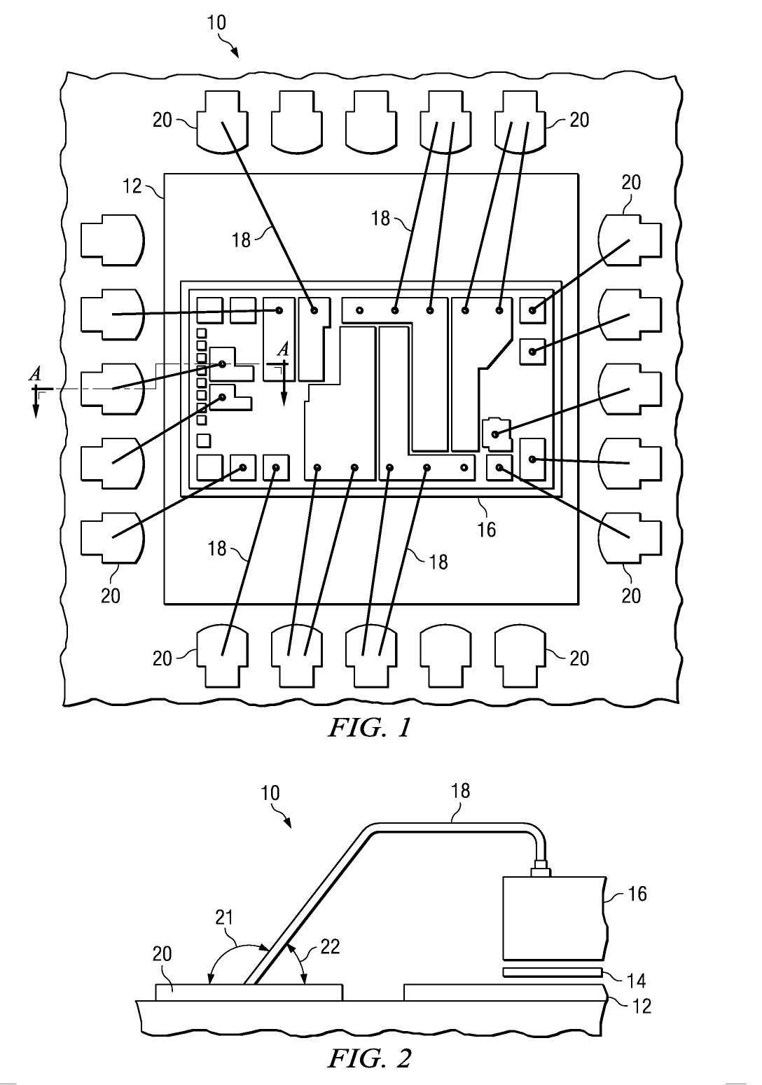

in FIG. 1, a standard semiconductor 10 is shown wherein a die 16 is coupled to a lead frame die 12. Die 16 and lead frame die 12 are bonded to one another, and may be electrically connected to one another. In the example shown in FIG. 1, die 16 comprises an integrated circuit wherein a plurality of conductive leads 18 are operable to connect die 16 to a plurality of lead fingers 20.

FIG. 2 shows a partial cross-sectional view A-A of the standard semiconductor 10 of FIG. 1. And more particularly, FIG. 2 shows how conductive leads 18 couple die 16 to the plurality of lead fingers 20. Once die 16 and lead frame die 12 are physically bonded to one another, the plurality of conductive leads 18 may be electrically coupled to a plurality of bonding pads (not shown) associated with the plurality of lead fingers 20 in order to electrically couple die 16 to lead fingers 20.

A standard capillary which has a goldwire, for example, extending through a bore enables to dispense conductive leads 18 by moving the capillary from die 16 to lead fingers 20 with the application of ultrasonic energy in a standard manner. In more details, capillary is lifted vertically from die 16 moves toward a selected lead finger 20 and then lowers as it approaches the selected lead finger 20 with an inner angle 22 (or outer angle 21) to form a stitch bond on the selected lead finger 20. The angle of approach or the inner angle 22 of the capillary determines the angle formed by the conductive lead 18 threaded through the bore of the capillary with the surface of the selected lead finger 20. The higher the inner angle 22 is, the more important the stress on the heel of the stitch bond will be. A standard angle of approach is very often above 60 degrees. It can even reach 90 degrees to become vertical to the surface of the lead finger 20.

Different types of stress are applied on the heel of the stitch bond: thermal stress and mechanical stress. These stresses tend to increase the risk of crack of the heel of the stitch bond and therefore of breaking the electrical contact between die 16 and the associated lead finger 20. Therefore, the angle of approach of the capillary should be reduced to an acceptable minimum.

Lead after lead, the capillary is making the looping routine between, die 16 and the plurality of lead fingers 20 with the goldwire being threaded through the bore of the capillary. The capillary is then making the same stitch bond with the goldwire on all the lead fingers 20 with the application of ultrasonic energy. If the angle of approach of capillary is reduced for all the lead fingers 20, the risk of breaking the heels of all the stitch bonds will also be drastically reduced, which will consequently increase the reliability of the semiconductor.

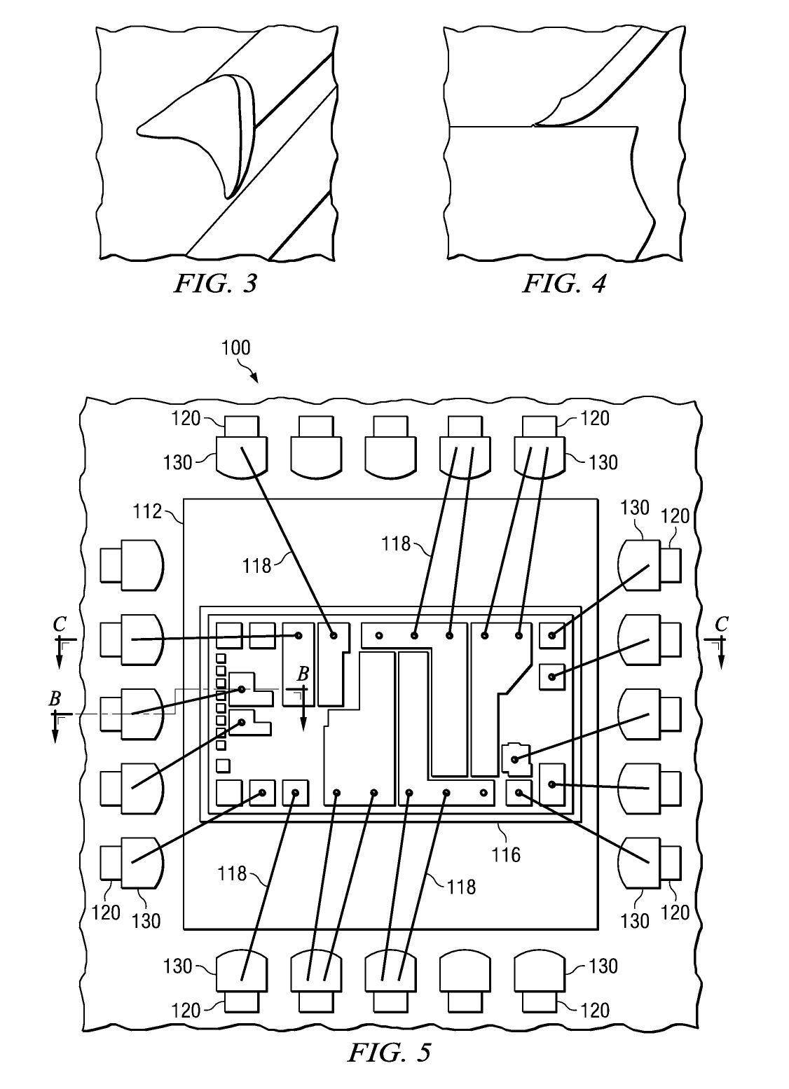

FIG. 3 shows the heel of a stitch bond on a lead finger in a perspective view. If the angle of approach of the capillary is high, the surface of contact between lead 18 and lead finger 20 is reduced.

FIG. 4 shows a small crack of the heel of a stitch bond in an elevation view. The small crack appears due to the thermal stress and mechanical stress that are applied to the heel of the stitch bond. The inner angle 22 formed between lead 18 and the surface of the lead finger 20 should be reduced as much as possible to limit the thermal and mechanical stresses on the heel of the stitch bond and to increase the quality of the downhill wire bonding and the reliability of the semiconductor.

Therefore, in order to strengthen the heel of the stitch bond, the angle of approach of the capillary should be as low as possible to increase the surface of contact between leads 18 and lead fingers 20.

One factor that will favor the reduction of the angle of approach of the capillary is the height at which the capillary is lifted vertically from die 16 before it moves toward the lead fingers 20. The height should be as low as possible in order to have a nearly horizontal approach to the lead fingers 20.

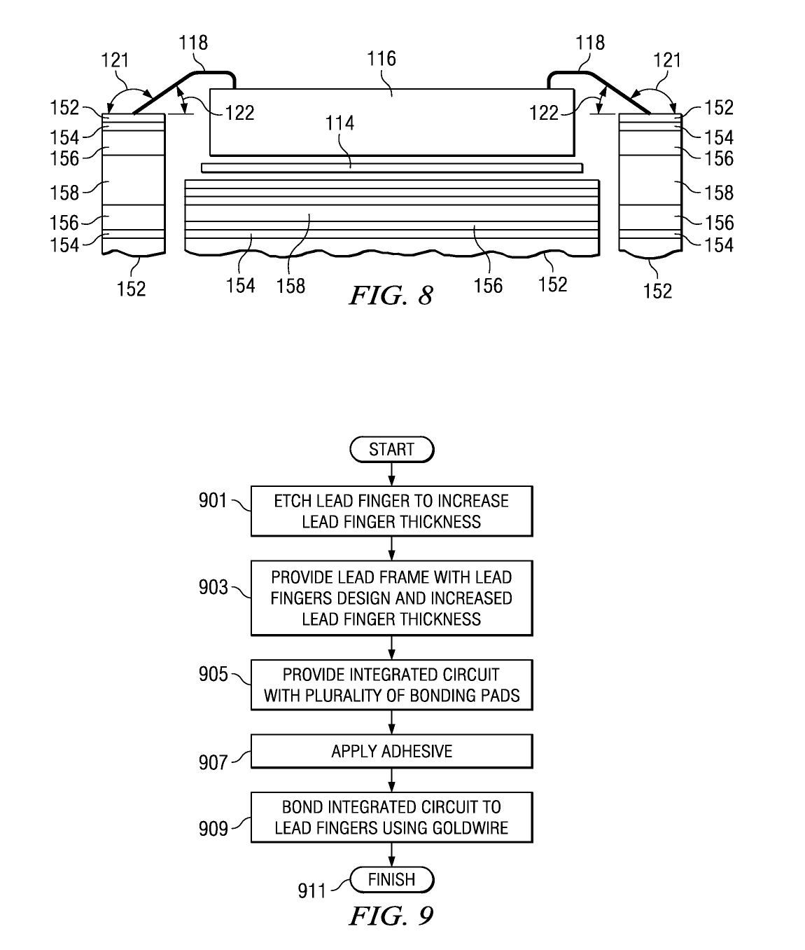

To avoid damaging the goldwire, the capillary is lifted vertically above the plane of the bond pad of die 16 at a height which is generally between 0.010 to 0.015 inches. However, in a preferred embodiment, this height may be reduced to 0.006 inches in thinner packages but cannot cross beyond this limit since the goldwire may be damaged and cracked by a smaller loop height. In a preferred embodiment, the reduction in the height of the capillary lift is shown in FIG. 7b and FIG. 8.

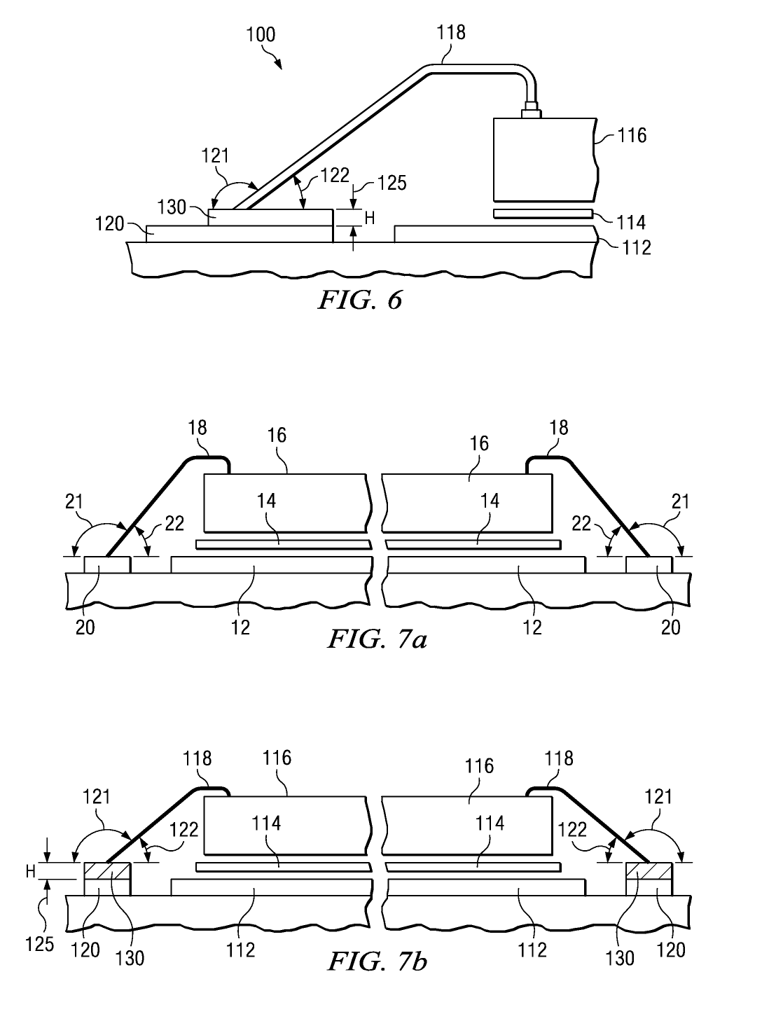

Another factor that will favor the reduction of the angle of approach of the capillary is to etch the stitch platform or the lead finger to increase its height by a reasonable amount so that the angle of approach of the capillary is as low as possible, which will be described in more details in FIG. 5, FIG. 6 and FIG. 7b. It should be kept in mind that the term “stitch platform” is a generic term to designate the area of the stitch bond. The area of the stitch platform depends on the application of the semiconductor. In a preferred embodiment, the lead finger is the whole area of the stitch platform. In other embodiments, the stitch platform can just be portion of the lead finger or can be physically located independently from the lead finger.

FIG. 5 is a plan view of a QFN L-lead design, with an increased stitch platform on the lead finger in a preferred embodiment. A semiconductor 100 is shown wherein a die 116 is coupled to a lead frame die 112. Die 116 and lead frame die 112 are bonded to one another. In some embodiments, die 116 is electrically connected to lead frame die 112. In FIG. 5, die 116 comprises an integrated circuit wherein a plurality of conductive leads 118 are operable to connect die 116 to a plurality of lead fingers 120. Lead fingers 120 has an increased thickness shown with a shaded area 130 that enables to reduce the angle of the approach of the capillary during the downhill wire bonding of conductive leads 118.

In a preferred embodiment, lead fingers 120 can be, for example, a layer of polyimide film to which is secured a copper trace layer by means of adhesive layer. Prior to electrically connecting die 116 to lead frame die 112, die 116 and lead frame die 112 are physically bonded to one another via an adhesive 114 (shown in FIG. 2). The adhesive 114 may comprise a fluid-like epoxy that is operable to be cured by an application of heat thereto.

FIG. 6 is a partial cross-sectional view B-B of the QFN L-lead design, with the increased stitch platform or increased lead finger according to the present invention. Die 116 are connected to the plurality of lead fingers 120 by conductive leads 118. All lead fingers 120 have an increased stitch platform by a height H that can be for instance more than 13 mils or more than 100 microns. In a preferred embodiment, the thickness of lead fingers 120 is increased from 203 microns to 333 microns, which is represented by a shaded area 130. As in the conventional semiconductor, once die 116 and lead frame die 112 are physically bonded to one another, the plurality of conductive leads 118 are electrically coupled to a plurality of bonding pads (not shown) associated with the plurality of lead fingers 120 in order to electrically couple die 116 to lead fingers 120. In a preferred embodiment, the plurality of conductive leads 118 are made of goldwire.

A capillary which uses goldwire as conductive leads 118 moves its bore from die 116 to the increased stitch platform of lead fingers 120 using the application of ultrasonic energy in a standard manner. In more details, the capillary is lifted vertically from die 116, moves toward a selected lead finger 120 with the increased stitch platform and then lowered as it approaches the selected lead finger 120 with an inner angle 122 (or outer angle 121). The inner angle 122 is lower than the previously mentioned inner angle 22, provided that the coordinates of the stitch between the two configurations without and with increased stitch platform did not change (on the OXY axis) but only for its vertical position (OZ).

The angle of approach or the inner angle 122 of the capillary determines the angle formed by conductive lead 118 threaded through the bore of the capillary with the surface of lead finger 120. As previously mentioned, the higher the inner angle 122 is, the more important the stress on the heel, of the stitch bond will be. In a preferred embodiment, the angle of approach of the capillary is reduced to less than 45 degrees, for instance between 35-40 degrees.

FIGS. 7a and 7b show the comparison of partial cross-sectional view C-C between a design without an increased stitch platform or lead finger and a design with an increased stitch platform or lead finger and a reduction in the height of capillary lift. Both figures enable to show how the angle of approach 22 corresponding to a configuration without the increased stitch platform can be reduced to the angle of approach 122 corresponding to a configuration with the increased stitch platform and with a reduction in the height of capillary lift. It is not necessary to combine the increased stitch platform with the reduction in the height of capillary lift to reduce the angle of approach 22 to 122. But by combining both factors, the angle of approach is even more reduced.

FIG. 8 is a partial cross-sectional view C-C of another QFN L-lead design illustrating the compounds used with an increased stitch platform. The integrated circuit 116 is bonded to the lead frame die 112 by an adhesive 114. The compounds used for lead fingers 120 may be identical to the ones used for lead frame die 112. For instance in a preferred embodiment, a first layer of Copper base 158 is coated on both sides by a layer of Nickel (Ni) 156 with a thickness of 1 to 2 microns, which are then coated on both sides by a layer of Palladium (Pd) with a thickness of 0.02 to 0.1 micron, which are then coated by a thin layer of Gold (Au) with a thickness of 0.003 to 0.009 micron. In other embodiments, the plurality of lead fingers 120 or the lead frame die 112 may comprise compounds such as metal or metal allow including one or more copper, silver, gold, nickel, aluminum, palladium and titanium.

In a preferred embodiment, the total thickness of each lead finger 120 which has an increased thickness 130 represented by height H, can be for instance more than 333 microns. The additional height indicated by H may be for instance equivalent to 13 mils or more than 100 microns, represents an increase by more than 50%, since the thickness of lead fingers 120 is increased from 203 microns to total of 333 microns.

FIG. 9 is a block diagram of an exemplary method of manufacturing a QFN L-lead with an increased stitch platform or lead finger. At step 901, the lead fingers are etched to increase the thickness of the stitch platform. In some embodiment, the stitch platform represents the whole surface of the lead finger. At step 903, the lead frame is provided with lead fingers design and increased lead finger thickness. The lead frame and the lead fingers can comprise the same compounds or different compounds. At step 907, an adhesive is applied to one or more of the interior regions. The adhesive, for example, comprises one or more components, such as a fluid-like resin. At step 909, the integrated circuit of the die is bonded to the lead fingers using goldwire dispensed by a capillary.

Though the invention has been described with respect to a specific preferred embodiment thereof, many variations and modifications will, immediately become apparent to those skilled in the art. The present invention, and many of its intended advantages, will be understood from the foregoing description and it will be apparent that, although the invention and its advantages have been described in detail various changes, substitutions and alterations may e made in the manner, procedure and details thereof, without departing from the spirit and scope of the invention.

It is therefore the intention that the appended claims be interpreted as broadly as possible in view of the prior art to include all such variations and modifications.

What is claimed is:

1. A method of downhill wire bonding between an integrated circuit and a plurality of lead fingers comprises the steps of:
(a) forming a stitch bond on a wire bonding location on a die pad of the integrated circuit;
(b) lifting vertically the wire by a height;
(c) moving the wire away from the wire bonding location on said die pad of the integrated circuit to one of said plurality of lead fingers;
(d) approaching one of said plurality of lead fingers with a reduced angle of approach;
(e) forming a stitch bond on one of said plurality of lead fingers; and
(f) bonding said one of said plurality of lead fingers to said die pad of the integrated circuit with a bonding wire which has a reduced angle with the surface of the lead finger.

2. The method of downhill wire bonding according to claim 1 where the angle of approach is reduced by increasing a thickness of the plurality of lead fingers.

3. The method of downhill wire bonding according to claim 1 wherein the angle of approach is reduced by minimizing a height by which the wire is lifted from the wire location on said die pad of the integrated circuit.

4. The method of downhill wire bonding according to claim 1 wherein the angle of approach is reduced by minimizing a height by which the wire is lifted from the wire location on said die pad of the integrated circuit, and by increasing a thickness of the plurality of lead fingers.

5. The method of downhill wire bonding according to claim 2 wherein the thickness of each of the plurality of lead fingers is increased by 50% from 203 microns to 330 microns.

6. The method of downhill wire bonding according to claim 3 wherein the height by which the wire is lifted is reduced to 0.006 inches.

7. The method of downhill wire bonding according to claim 1 wherein the plurality of lead fingers comprise one or more copper, aluminum, gold, silver, nickel, palladium and titanium.

8. The method of downhill wire bonding according to claim 1 wherein the reduced angle of approach is less than 45 degrees, and is preferably between 35-40 degrees.

9. The method of downhill wire bonding according to claim 1 to be used for QFN L-lead semiconductor packages.

10. The method of downhill wire bonding according to claim 1 wherein said bonding wire is a gold allow.

11. A method of downhill wire bonding between an integrated circuit and a plurality of lead fingers comprises the steps of:
(a) etching each said plurality of lead fingers to increase lead finger thickness;
(b) providing lead frame with said plurality of lead fingers with increased thickness;
(c) providing integrated circuit with a plurality of bonding pads;
(d) applying adhesive to bond integrated circuit to a lead frame die; and
(e) approaching a capillary with a reduced angle of approach to bond said plurality of bonding pads of the integrated circuit to said plurality of lead fingers with a bonding wire threaded through the bore of a capillary.

12. The method of downhill wire bonding according to claim 11 further comprises the step of minimizing a height by which the capillary is lifted to move from said plurality of bonding pads of the integrated circuit to said plurality of lead fingers.

13. The method of downhill wire bonding according to claim 11 wherein the thickness of each said plurality of lead fingers is increased by 50% from 203 microns to 330 microns.

14. The method of downhill wire bonding according to claim 12 wherein the height by which the capillary is lifted is reduced to 0.006 inches.

15. The method of downhill wire bonding according to claim 11 wherein the reduced angle of approach is less than 45 degrees, and is preferably between 35-40 degrees.

16. The method of downhill wire bonding according to claim 11 to be used for QFN L-lead semiconductor packages.

17. A QFN L-lead semiconductor package comprising:
an integrated circuit bonded to a lead frame die with an adhesive, said integrated circuit having a plurality of die pads; and
a plurality of lead fingers electrically wire bonded with said plurality of die pads of said integrated circuit;
wherein each said plurality of lead fingers presents an increased stitch platform thickness.

18. The QFN L-lead semiconductor package according to claim 17 wherein the increased stitch platform is increased by 50% from 203 microns to 330 microns.

19. The QFN L-lead semiconductor package according to claim 17 wherein the plurality of lead fingers comprise one or more copper, aluminum, gold, silver, nickel, palladium and titanium.

20. The QFN L-lead semiconductor package according to claim 17 wherein the angle formed by the wire with a surface of each said plurality of lead fingers is less than 45 degrees, and is preferably between 35-40 degrees.
